(19) United States
(12) Patent Application Publication
(10) Pub. No.: US 2017/0146570 A1
(43) Pub. Date: May 25, 2017

(54) PROBE CARD AND MULTILAYER CIRCUIT BOARD THIS PROBE CARD INCLUDES

(71) Applicant: Murata Manufacturing Co., Ltd., Kyoto (JP)

(72) Inventor: Tadaji TAKEMURA, Kyoto (JP)

(21) Appl. No.: 15/423,755

(22) Filed: Feb. 3, 2017

Related U.S. Application Data
(63) Continuation of application No. PCT/JP2015/072453, filed on Aug. 7, 2015.

(30) Foreign Application Priority Data
Aug. 11, 2014 (JP) 2014-163875

(51) Int. Cl. G01R 1/36; H05K 1/03; G01R 31/26; H05K 1/18; G01R 1/073; G01R 1/20; H05K 1/14; H05K 1/09

(52) U.S. Cl. CPC G01R 1/36; H05K 1/144; H05K 1/036; H05K 1/0306; H05K 1/092; H05K 1/181; G01R 1/07342; G01R 1/20; G01R 31/2601; H05K 2201/0175; H05K 2201/10181

(57) ABSTRACT

A probe card for use in electrical testing of a device under test includes a mother substrate, a multilayer circuit board mounted on one main surface of the mother substrate, an outer electrode on the mother substrate, a coupling electrode on the main surface of the multilayer circuit board opposite the mother substrate to which a probe pin for supplying power to the device under test is connected, a power line PL coupling the outer electrode and the coupling electrode together, and a blowout portion including fuse wiring, the fuse wiring inserted in the power line PL and having a smaller current capacity than the power line PL. The power line PL has an exposed portion that is exposed on the surface of the multilayer circuit board, and the blowout portion is in the exposed portion of the power line PL.

### CROSS-REFERENCE TO RELATED APPLICATIONS

This application is a continuation of International Application No. PCT/JP2015/072453 filed on Aug. 7, 2015 which claims priority from Japanese Patent Application No. 2014-163875 filed on Aug. 11, 2014. The contents of these applications are incorporated herein by reference in their entireties.

### TECHNICAL FIELD

### Background

The present disclosure relates to a probe card for use in electrical testing of a device under test and a multilayer circuit board this probe card includes.

Probe cards, which are used for electrical testing of semiconductor devices such as LSI devices, commonly incorporate a ceramic multilayer substrate as a substrate in which wiring is formed to interface outer electrodes of a mother substrate and probe pins. In recent years, the increased integration of semiconductor devices and the resulting increased number and reduced pitch of their terminals have led to the use of multilayer circuit boards, which are ceramic multilayer substrates in which some layers have been replaced with resin layers such as polyimide layers for easy formation of delicate wiring.

For example, a multilayer circuit board 100 described in Patent Document 1 includes, as illustrated in FIG. 10, a ceramic multilayer body 101 that is a stack of multiple ceramic layers 101a and a resin multilayer body 102 that is a stack of multiple resin layers 102a, with the resin multilayer body 102 on the ceramic multilayer body 101. On the top surface of the multilayer circuit board 100, there are multiple tightly pitched surface electrodes 103 each to be connected to a probe pin. On the bottom surface of the multilayer circuit board 100, there are back electrodes 104 corresponding to the surface electrodes 103 and connected respectively to the corresponding surface electrodes 103. The back electrodes 104 are for connection to a mother substrate.

Inside the resin multilayer body 102 and the ceramic multilayer body 101 there is a rewiring structure that makes the pitch between adjacent back electrodes 104 wider than that between adjacent surface electrodes 103.

The formation of such a rewiring structure requires that the wires that form the wiring in the resin multilayer body 102, which is closer to the surface electrodes 103, be thin and tightly pitched. The resin multilayer body 102 is thus composed of resin layers 102a such as polyimide layers so that delicate wiring can be formed therein. The ceramic multilayer body 101 is composed of ceramic layers 101a, which are more rigid than the resin layers 102a and have a coefficient of linear expansion close to those of test media, e.g., IC wafers, because it has relatively large room inside for the formation of wiring. This configuration of the multilayer circuit board 100 allows for increasing the number of terminals and electrical testing of the semiconductor devices in recent years, which have tightly pitched terminals.

Patent Document 1: Japanese Unexamined Patent Application Publication No. 2011-9694 (see paragraphs 0019 to 0022, FIG. 1, etc.)

### BRIEF SUMMARY

Probe cards of this kind can be subjected to, for example, a large current flow that exceeds their maximum allowable current at their power line, a line for carrying power supply to the power terminal of the device under test. This used to result in thermal melting of and damage to the probe pin connected to the power line, but now places the wiring electrodes in the polyimide or similar resin layers 102a (resin multilayer body 102) at high risk of disconnection because the wiring electrodes (power line) in the multilayer circuit board 100, those in the resin layers 102a in particular, are thin owing to the increased terminals of devices under test in recent years. Disconnection of any wiring electrode in the multilayer circuit board 100 necessitates replacing the multilayer circuit board 100 as a whole, in which case repairing the probe card costs more than with the replacement of probe pins.

Made in light of the above problem, the present disclosure is intended to provide a probe card that can be repaired at reduced cost after unexpectedly large current flows through its power line.

A probe card according to the present disclosure is for use in electrical testing of a device under test and includes a mother substrate, a multilayer circuit board mounted on one main surface of the mother substrate, a power-carrying electrode on the mother substrate, a power interface electrode on the main surface of the multilayer circuit board opposite the mother substrate to which a probe pin for carrying power supply to the device under test is connected, a power line coupling the power-carrying electrode and the power interface electrode together, and a blowout portion including fuse wiring, the fuse wiring inserted in the power line and having a smaller current capacity than the power line. The probe card is characterized in that the multilayer circuit board includes a ceramic layer and a resin layer on the ceramic layer, the ceramic layer on the mother substrate side, that the power line has an exposed portion that is exposed on the surface of the mother substrate or multilayer circuit board, and that the blowout portion is in the exposed portion of the power line.

With this configuration, fuse wiring having a smaller current capacity than the power line lies inserted in the power line. Even if unexpectedly large current flows through the power line, the fuse wiring blows out first and makes the power line open. No current flows through the power line beyond its current capacity, and damage to the power line is prevented.

Furthermore, there is a blowout portion including the fuse wiring in an exposed portion of the power line. Even if the fuse wiring blows out and makes the power line open, the user does not need to replace the multilayer circuit board in the subsequent repair work. The repair cost needed following a current flow through the power line exceeding its maximum allowable current is therefore reduced.

In the blowout portion, there may be a chip component formed with the fuse wiring. This allows the user to repair the open power line simply by replacing the chip component even if the fuse wiring blows out.

The fuse wiring may have a line width smaller than that of the power line. In this case, it is easy to form fuse wiring that has a smaller current capacity than the power line.

The fuse wiring may be formed using conductive paste. In this case, it is easy and inexpensive to form the fuse wiring and repair blown-out fuse wiring.

The blowout portion may be on the multilayer circuit board. In this case, there is provided a probe card formed with the blowout portion on the multilayer circuit board.

The power interface electrode may be in the middle of the main surface of the multilayer circuit board opposite the mother substrate in plan view (viewed in a direction perpendicular to the main surface of the multilayer circuit board) with the blowout portion in a peripheral portion of the main surface opposite the mother substrate. Keeping the probe pin connected to the power interface electrode separate from the blowout portion in this way allows for improved efficiency in the repair work following the blowing out of the fuse wiring.

The blowout portion may be on the mother substrate. In this case, the user can repair blown-out fuse wiring without necessarily disassembling the mother substrate and the multilayer circuit board.

A multilayer circuit board according to the present disclosure is one a probe card for use in electrical testing of a device under test includes, and the circuit board includes a ceramic layer, a resin layer on the ceramic layer, a power interface electrode on the main surface of the resin layer opposite the ceramic layer to which a probe pin for carrying power supply to the device under test is connected, a power-carrying outer electrode on the main surface of the ceramic layer opposite the resin layer, a power line coupling the power-carrying outer electrode and the power interface electrode together, and a blowout portion including fuse wiring, the fuse wiring inserted in the power line and having a smaller current capacity than the power line. The multilayer circuit board is characterized in that the power line has an exposed portion that is exposed on the surface of the resin layer, and that the blowout portion is in the exposed portion of the power line.

In this configuration, there is provided a multilayer circuit board that can be repaired at reduced cost following a current flow through the power line exceeding its maximum allowable current.

Another multilayer circuit board according to the present disclosure is one a probe card for use in electrical testing of a device under test includes, and the circuit board includes a ceramic layer, a resin layer on the ceramic layer, the resin layer smaller in area than the ceramic layer in plan view, a power interface electrode on the main surface of the resin layer opposite the ceramic layer to which a probe pin for carrying power supply to the device under test is connected, a power-carrying outer electrode on the main surface of the ceramic layer opposite the resin layer, a power line coupling the power-carrying outer electrode and the power interface electrode together, and a blowout portion including fuse wiring, the fuse wiring inserted in the power line and having a smaller current capacity than the power line. The power line may have an exposed portion that is exposed on the main surface of the ceramic layer facing the resin layer and in a region not occupied by the resin layer, and the blowout portion may be in the exposed portion of the power line. In this configuration it is possible to, for example, install a chip component formed with the fuse wiring on the ceramic layer. This leads to improved adhesion between the multilayer circuit board and the chip component.

According to the present disclosure, fuse wiring having a smaller current capacity than the power line lies inserted in the power line. Even if unexpectedly large current flows through the power line, the fuse wiring blows out first and makes the power line open. No current flows through the power line beyond its current capacity, and damage to the power line is prevented. Furthermore, there is a blowout portion including the fuse wiring in an exposed portion of the power line. Even if the fuse wiring blows out and makes the power line open, the user does not need to replace the multilayer circuit board in the subsequent repair work. The repair cost needed following a current flow through the power line exceeding its maximum allowable current is therefore reduced.

### BRIEF DESCRIPTION OF THE SEVERAL VIEWS OF THE DRAWINGS

FIG. 1 is a cross-sectional view of a probe card according to Embodiment 1 of the present disclosure.

FIG. 2 is a cross-sectional view of the multilayer circuit board in FIG. 1.

FIG. 3 is a cross-sectional view of a multilayer circuit board according to Embodiment 2 of the present disclosure.

FIG. 4 is a cross-sectional view of a multilayer circuit board according to Embodiment 3 of the present disclosure.

FIG. 5 is a plan view of the multilayer circuit board in FIG. 4.

FIG. 6 is a diagram for illustrating a variation of fuse wiring.

FIG. 7 is a partial cross-sectional view of a probe card according to Embodiment 4 of the present disclosure.

FIG. 8 is a cross-sectional view of a multilayer circuit board according to Embodiment 5 of the present disclosure.

FIG. 9 is a diagram for illustrating another variation of fuse wiring.

FIG. 10 is a cross-sectional view of a multilayer circuit board in a known probe card.

### DETAILED DESCRIPTION

### Embodiment 1

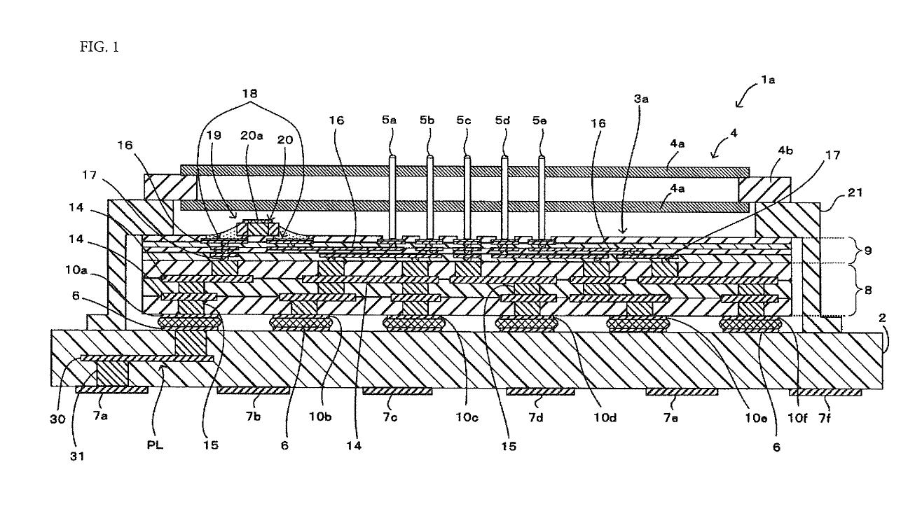

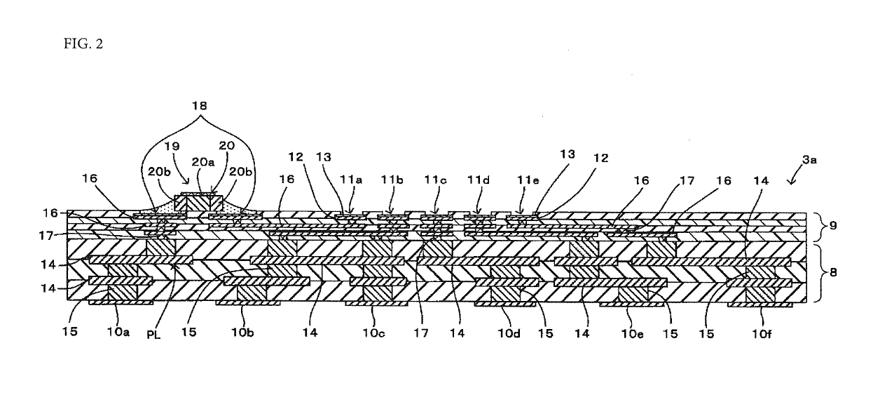

A probe card 1a according to Embodiment 1 of the present disclosure is described with reference to FIGS. 1 and 2. FIG. 1 is a cross-sectional view of the probe card 1a, and FIG. 2 is a cross-sectional view of the multilayer circuit board 3a in FIG. 1. FIG. 1 omits some of wiring electrodes and conductive vias formed in the mother substrate 2.

The probe card 1a according to this embodiment includes, as illustrated in FIG. 1, a mother substrate 2, a multilayer circuit board 3a mounted on one main surface of the mother substrate 2, and a probe head 4 holding multiple probe pins 5a to 5e each connected to the multilayer circuit board 3a. This probe card is for use in, for example, electrical testing of a device under test such as a semiconductor device.

The mother substrate 2 is formed with multiple mounting electrodes 6, which are used to mount the multilayer circuit board 3a, on one main surface and multiple outer electrodes 7a to 7f, which are for external connection, on the other main surface. The mounting electrodes 6 are coupled to predetermined ones of the outer electrodes 7a to 7f by wiring electrodes 30 and conductive vias 31 formed inside the mother substrate 2. The mother substrate 2 is formed of, for example, glass epoxy resin.

The multilayer circuit board 3a includes a ceramic layer 8 and a resin layer 9 on the ceramic layer 8, the ceramic layer 8 on the mother substrate 2 side. The ceramic layer 8 can be formed of various ceramic materials, including low-temperature co-fired ceramics (LTCCs) or high-temperature co-fired ceramics (HTCCs) based on borosilicate glass-containing ceramics (e.g., alumina). The resin layer 9 is formed of, for example, polyimide or other resins. In this embodiment, the ceramic layer 8 and the resin layer 9 both have a multilayer structure.

On the main surface of the ceramic layer 8 opposite the resin layer 9, there are multiple outer interface electrodes 10a to 10f for mounting onto the mother substrate 2. These outer interface electrodes 10a to 10f are soldered to predetermined ones of the mounting electrodes 6 on the mother substrate 2. On the main surface of the resin layer 9 opposite the ceramic layer 8, as illustrated in FIG. 2, there are multiple interface electrodes 11a to 11e to which the probe pins 5a to 5e, respectively, are to be connected. The outer interface electrodes 10a to 10f are formed of, for example, Cu, Ag, Al, or other metals. The interface electrodes 11a to 11e are each composed of, for example, a Cu or other underlying electrode 12 and a surface electrode 13 that is Ni/Au plating on the underlying electrode 12.

Inside the ceramic layer 8, there are wiring electrodes 14 and multiple conductive vias 15. The conductive vias 15 and the wiring electrodes 14 are each formed of Cu, Ag, Al, or other metals. The wiring electrodes 14 in the ceramic layer 8 are formed by, for example, screen printing using a conductive paste that contains any of such metals (e.g., Cu, Ag, or Al).

Inside the resin layer 9, there are wiring electrodes 16 and multiple conductive vias 17. The wiring electrodes 16 can be formed by, for example, depositing Ti film as an underlying electrode on main surfaces of predetermined layers constituting the resin layer 9 using sputtering or other techniques, depositing Cu film on the Ti film using sputtering or other techniques again, and then depositing another Cu film on the preexisting Cu film using electrolytic or electroless plating. The wiring electrodes 16 in the resin layer 9 are formed in a fine pattern through photolithography. The wiring electrodes 14 in the ceramic layer 8, formed by screen printing or similar techniques, are in a pattern of thick film, and the wiring electrodes 16 in the resin layer 9, formed by sputtering or similar techniques, are in a pattern of thin film. Formed in narrow lines through photolithography as mentioned above, the wiring electrodes 16 in the resin layer 9 have smaller maximum allowable current and are less resistant to current flow than the wiring electrodes 14 in the ceramic layer 8.

The interface electrodes 11a to 11e are each electrically coupled to predetermined one(s) of the outer electrodes 7a to 7f on the farther main surface of the mother substrate 2. Specifically, as illustrated in FIGS. 1 and 2, the interface electrodes 11a to 11e are each coupled to predetermined one(s) of the outer electrodes 7a to 7f by the wiring electrodes 16 and conductive vias 17 in the resin layer 9, the wiring electrodes 14 and conductive vias 15 in the ceramic layer 8, and the wiring electrodes 30 and conductive vias 31 in the mother substrate 2.

For example, the interface electrode 11a, one of the interface electrodes 11a to 11e and connected to the probe pin 5a which is a carrier of power supply to the device under test, is coupled to the outer interface electrode 10a in the ceramic layer 8 by some wiring electrodes 16 and conductive vias 17 in the resin layer 9 and some wiring electrodes 14 and conductive vias 15 in the ceramic layer 8. The outer interface electrode 10a is soldered to the far left mounting electrode 6, in FIG. 1, of the mounting electrodes 6 formed on one main surface of the mother substrate 2. This mounting electrode 6 is coupled to the outer electrode 7a on the other main surface of the mother substrate 2 by some wiring electrodes 30 and conductive vias 31 in the mother substrate 2. In this way, a power line PL is formed through the multilayer circuit board 3a and the mother substrate 2, coupling the interface electrode 11a, which is connected to the power-carrying probe pin 5a, to the outer electrode 7a formed on the farther main surface of the mother substrate 2.

The power line PL has an exposed portion 18 that is exposed on the surface of the multilayer circuit board 3a (the main surface of the resin layer 9 opposite the ceramic layer 8). In this exposed portion 18, there is a blowout portion 19 that includes fuse wiring 20a. Specifically, the blowout portion 19 is a place to position a chip component 20 formed with the fuse wiring 20a (a so-called fuse chip). The exposed portion 18 of the power line PL is segmented halfway into land electrodes for the mounting of the chip component 20, and the chip component 20 is solder-mounted to join the segments together. The segments of the power line PL divided at the exposed portion 18 are electrically coupled together by the fuse wiring 20a of the chip component 20; that is, the fuse wiring 20a is connected in series with (inserted in) the power line PL.

The chip component 20 includes, for example, a ceramic body substantially rectangular in plan view and two electrodes 20b, one at one end portion and one at the other. Fuse wiring 20a makes these two electrodes 20b conduct. The fuse wiring 20a has smaller maximum allowable current (current capacity) than the wiring electrode 16 in the resin layer 9 with the smallest maximum allowable current among the wiring electrodes 14 and 16 formed in the mother substrate 2 and the multilayer circuit board 3a. In this embodiment, the interface electrodes 11a to 11e, each connected to a predetermined one of the probe pins 5a to 5e, are in a middle portion of the multilayer circuit board 3a in plan view, and the blowout portion 19 is in a peripheral portion of the multilayer circuit board 3a in plan view.

Consequently, the interface electrode 11a of the multilayer circuit board 3a, to which the probe pin 5a which is a carrier of power supply to the device under test is connected, corresponds to the “power interface electrode” according to the present disclosure. The outer interface electrode 10a of the multilayer circuit board 3a, electrically coupled to this interface electrode 11a, corresponds to the “power-carrying outer electrode” according to the present disclosure, and the outer electrode 7a of the mother substrate, electrically coupled to this outer interface electrode 10a, corresponds to the “power-carrying electrode” according to the present disclosure.

The probe head 4, holding the probe pins 5a to 5e, includes, as illustrated in FIG. 1, two substantially parallel retainer plates 4a spaced at a predetermined distance and a spacer 4b between the two retainer plates 4a, and is securely fit to a covering body 21 fastened to the mother substrate 2.

According to this embodiment, therefore, fuse wiring 20a having smaller maximum allowable current (current capacity) than the power line PL (wiring electrode 16) lies inserted halfway in the power line PL. Even if unexpectedly large current flows through the power line PL, the fuse wiring 20a blows out first and makes the power line PL open. No current flows through the power line PL beyond its maximum allowable current, and damage to the power line PL is prevented.

Furthermore, there is a blowout portion 19 in an exposed portion 18 of the power line PL. Even if the fuse wiring 20a blows out and makes the power line PL open, the open power line PL can be restored by installing a new chip component 20. That is, the user does not need to replace the multilayer circuit board 3a in the restoration (repair) of the power line PL. The restoration cost needed following a current flow through the power line PL exceeding its maximum allowable current is therefore reduced.

Furthermore, the interface electrodes 11a to 11e, each connected to a predetermined one of the probe pins 5a to 5e, are in a middle portion of the multilayer circuit board 3a (the main surface of the resin layer 9 opposite the ceramic layer) in plan view, and the blowout portion 19 is in a peripheral portion of the same main surface in plan view. The probe pins 5a to 5e, connected to the interface electrodes 11a to 11e, are therefore separate from the blowout portion 19, allowing for improved efficiency in the power line PL restoration work, i.e., the replacement of a chip component 20 having its fuse wiring 20a blown out with a new chip component 20.

### Embodiment 2

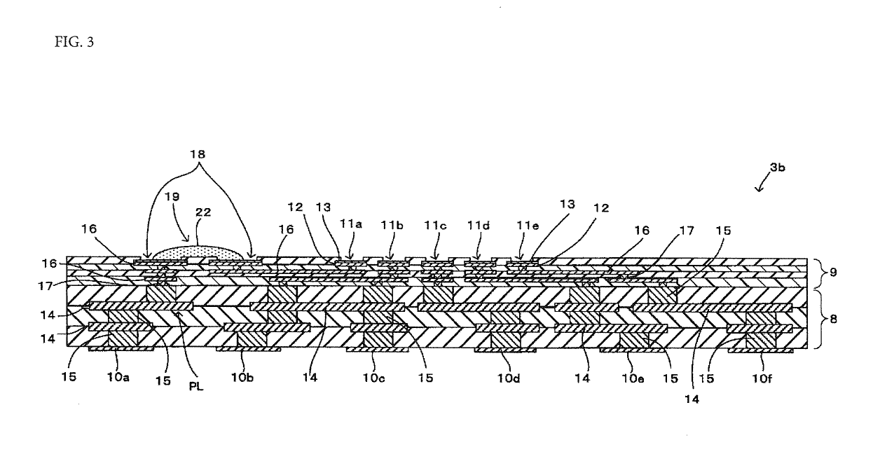

A multilayer circuit board 3b according to Embodiment 2 of the present disclosure is described with reference to FIG. 3. FIG. 3 is a cross-sectional view of the multilayer circuit board 3b according to Embodiment 2.

The multilayer circuit board 3b according to this embodiment differs from the multilayer circuit board 3a of Embodiment 1, described with reference to FIG. 2, in that the fuse wiring 22 in the blowout portion 19 is formed using conductive paste as illustrated in FIG. 3. The other elements are the same as those in the multilayer circuit board 3b of Embodiment 1 and thus are given the same reference numerals to avoid duplicating description.

In this case, the segments of the power line PL divided at the exposed portion 18 are joined together by fuse wiring 22 formed using conductive paste. The materials for the conductive paste include Ag, Cu, or any other metal filler and an organic solvent, and the amount of the metal filler has been adjusted to make the maximum allowable current of the fuse wiring 22 smaller than that of the power line PL (wiring electrode 16). This fuse wiring 22 can be formed in a pattern using techniques such as screen printing and dipping. When the fuse wiring 22 blows out, the user can either re-form the fuse wiring 22 using the conductive paste or, as in the probe card 1a according to Embodiment 1, install a chip component 20 formed with fuse wiring 20a in the blowout portion 19.

In this configuration, it is easy and inexpensive to form the fuse wiring 22 and to restore (repair) the power line PL after the fuse wiring 22 blows out.

### Embodiment 3

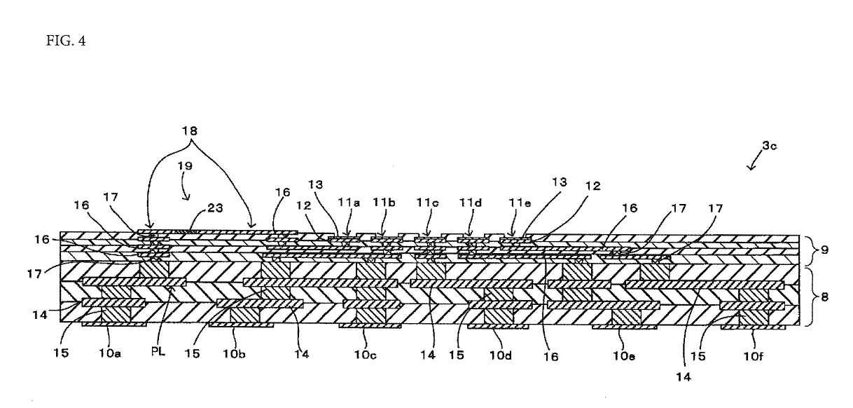

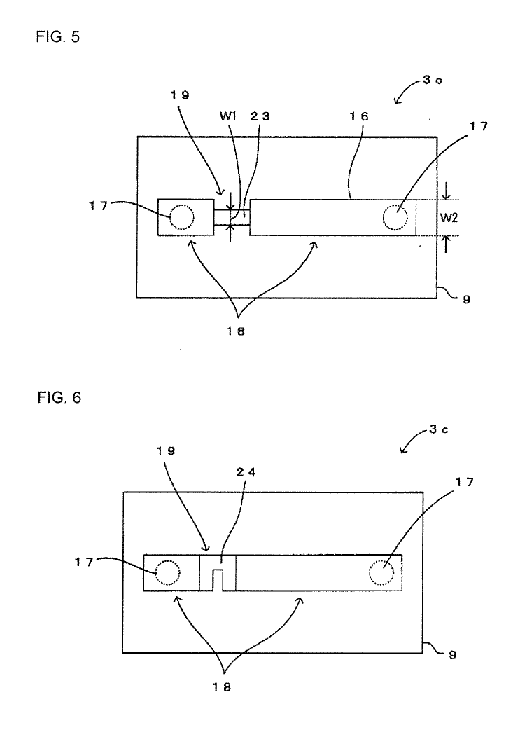

A multilayer circuit board 3c according to Embodiment 3 of the present disclosure is described with reference to FIGS. 4 and 5. FIG. 4 is a cross-sectional view of the multilayer circuit board 3c, and FIG. 5 is a plan view of the blowout portion 19.

The multilayer circuit board 3c according to this embodiment differs from the multilayer circuit board 3a of Embodiment 1, described with reference to FIG. 2, in that the fuse wiring 23 in the blowout portion 19 has a line width W1 smaller than the line width W2 of the power line PL as illustrated in FIG. 5. The other elements are the same as those in the multilayer circuit board 3a of Embodiment 1 and thus are given the same reference numerals to avoid duplicating description.

In this case, part of the power line PL is a wiring electrode 16 formed on the main surface of the resin layer 9 opposite the ceramic layer 8, and this wiring electrode 16 forms the exposed portion 18 of the power line PL. This wiring electrode 16 that forms the exposed portion 18 includes a blowout portion 19 halfway, and the fuse wiring 23 has a line width W1 smaller than the line width W2 of the wiring electrode 16 that forms the exposed portion 18 as illustrated in FIG. 5. The thickness of the fuse wiring 23 is substantially the same as that of the wiring electrode 16. With such a shape, fuse wiring 23 can be formed to have smaller maximum allowable current than that of the power line PL (wiring electrode 16). The fuse wiring 23 may be either integral with or separate from the wiring electrode 16 that forms the exposed portion 18 of the power line PL. After the fuse wiring 23 blows out, the user can restore the power line PL by placing a chip component 20 formed with fuse wiring 20a in the blowout portion 19 as in Embodiment 1 or by forming fuse wiring 22 using conductive paste as in Embodiment 2.

The wiring electrode 16 formed as the exposed portion 18 of the power line PL does not need to be entirely exposed on the surface of the resin layer 9. For example, it may be exposed on the surface of the resin layer 9 around the blowout portion 19 and otherwise covered with the resin layer 9. This leads to the protection of the wiring electrode 16.

In this configuration, it is easy and inexpensive to form fuse wiring 23 having smaller maximum allowable current than the power line PL.

### (Fuse Wiring Variation)

A variation of fuse wiring 23 is described with reference to FIG. 6. FIG. 6 is for illustrating a variation of fuse wiring 23 and corresponds to FIG. 5.

The fuse wiring 23 described above may optionally have a different shape as long as its maximum allowable current is smaller than that of the power line PL. For example, it is possible to cut a notch in one end, in the direction of line width, of the wiring electrode 16 within the blowout portion 19 as illustrated in FIG. 6 and use this notched, narrow-line portion as fuse wiring 24.

### Embodiment 4

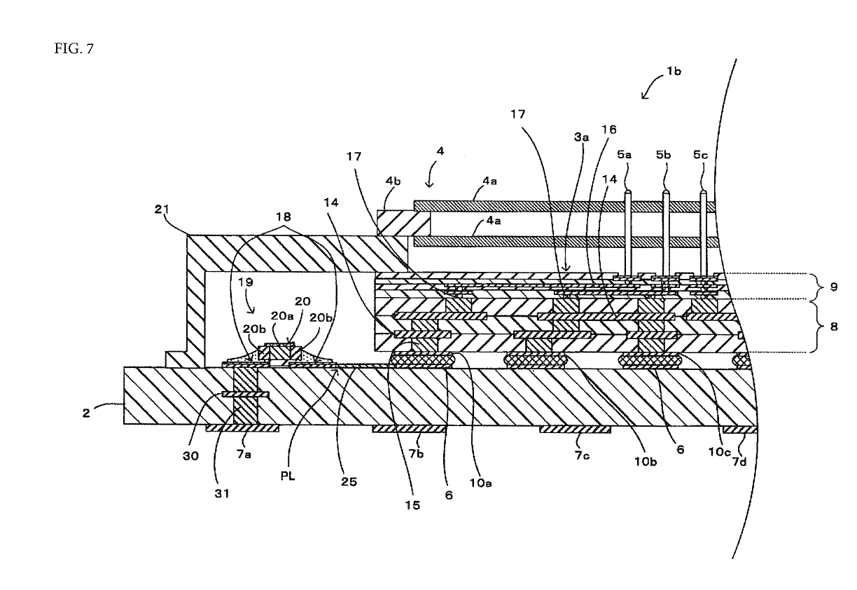

A probe card 1b according to Embodiment 4 of the present disclosure is described with reference to FIG. 7. FIG. 7 is a partial cross-sectional view of a probe card according to Embodiment 4.

The probe card 1b according to this embodiment differs from the probe card 1a of Embodiment 1, described with reference to FIG. 1, in that the blowout portion 19 is on the mother substrate 2 as illustrated in FIG. 7. The other elements are the same as or equivalent to those in the probe card 1a of Embodiment 1 and thus are given the same reference numerals to avoid duplicating description.

In this case, the exposed portion 18 of the power line PL is a wiring electrode 25 formed on one main surface of the mother substrate 2. This exposed portion 18 includes a blowout portion 19 which is, as in Embodiment 1, a place to mount a chip component 20 formed with fuse wiring 20a.

In this configuration, the user can restore (repair) an open power line PL simply by replacing the chip component 20 on the mother substrate 2, without necessarily disassembling the probe card 1b.

### Embodiment 5

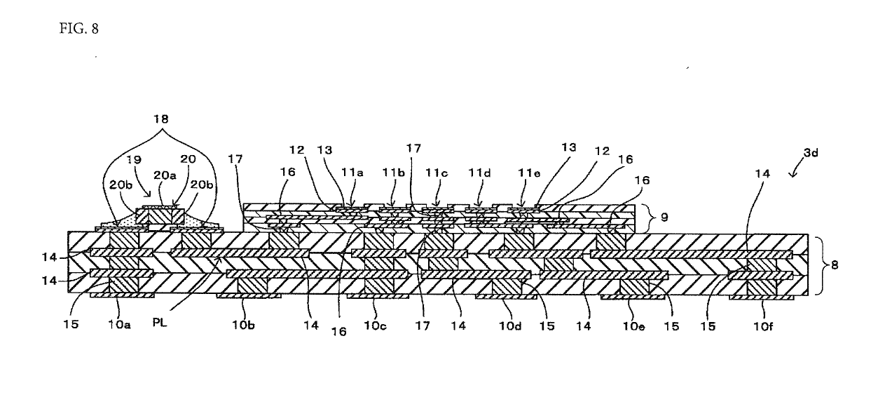

A multilayer circuit board 3d according to Embodiment 5 of the present disclosure is described with reference to FIG. 8. FIG. 8 is a cross-sectional view of the multilayer circuit board 3d.

The multilayer circuit board 3d according to this embodiment differs from the multilayer circuit board 3a of Embodiment 1, described with reference to FIG. 2, in that the resin layer 9 is smaller than the ceramic layer 8 and that the exposed portion 18 of the power line PL is on the main surface of the ceramic layer 8 facing the resin layer 9 (upper surface) and in a region not occupied by the resin layer 9 as illustrated in FIG. 8. The other elements are the same as those in the multilayer circuit board 3a of Embodiment 1 and thus are given the same reference numerals to avoid duplicating description.

In this configuration, it is possible to install a chip component 20 provided with fuse wiring 20a on the ceramic layer 8 side. This leads to improved adhesion between the multilayer circuit board 3d and the chip component 20 as compared with that in the multilayer circuit board 3a of Embodiment 1.

The present disclosure is not limited to the above embodiments. Besides the foregoing, various changes are possible unless they constitute departures from the gist of the disclosure. For example, the multilayer resin layers 9 in the above embodiments may alternatively have a single-layer structure. The number of layers in the ceramic layer 8 and that in the resin layer 9 can optionally be changed.

The fuse wiring 20a and 22 to 24, which have smaller maximum allowable current than the power line PL in the above embodiments, can have the smallest maximum allowable current including the probe pins 5a and 5e. This prevents the probe pins 5a to 5e from melting and being damaged when unexpectedly large current flows.

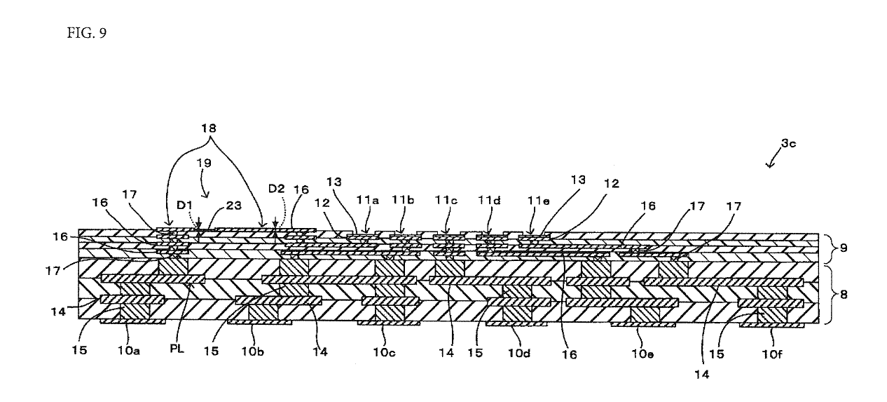

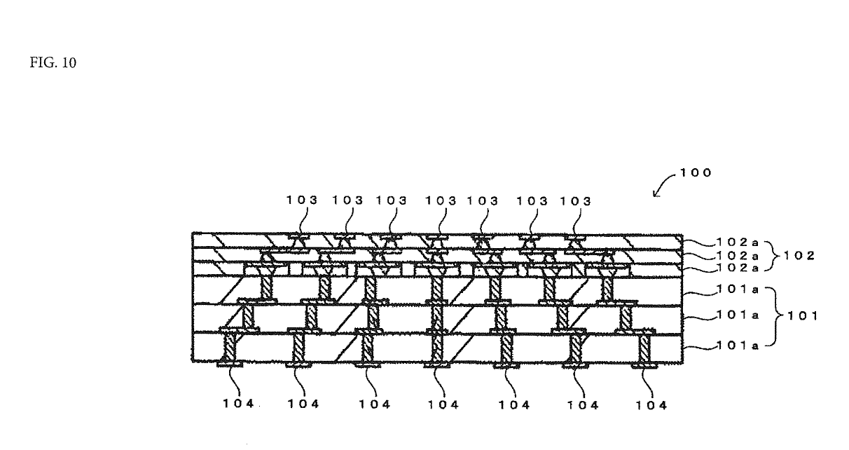

Although in Embodiment 3 the fuse wiring 23 has a line width W1 smaller than the line width W2 of the power line PL (wiring electrode 16) and this gives the wiring smaller maximum allowable current than that of the power line PL, the smaller maximum allowable current can also be obtained by, for example, making the thickness D1 of the fuse wiring 23 smaller than the thickness D2 of the power line PL (wiring electrode 16) as illustrated in FIG. 9. FIG. 9 illustrates a second variation of fuse wiring 23.

### INDUSTRIAL APPLICABILITY

The present disclosure is, furthermore, widely applicable to a variety of probe cards used in electrical testing of devices under test.

### REFERENCE SIGNS LIST

1a, 1b Probe card
2 Mother substrate
3a, 3b, 3c, 3d Multilayer circuit board
5a to 5e Probe pins
7a Outer electrode (power-carrying electrode)
8 Ceramic layer
9 Resin layer
10a Outer interface electrode (power-carrying outer electrode)
11a Interface electrode (power interface electrode)
18 Exposed portion
19 Blowout portion
20 Chip component
20a, 22 to 24 Fuse wiring
PL Power line

1. A probe card used in electrical testing of a device, the probe card comprising:
a mother substrate;
a multilayer circuit board mounted on one main surface of the mother substrate;
a power-carrying electrode on the mother substrate;
a power interface electrode on a main surface of the multilayer circuit board opposite to the mother substrate, the power interface electrode being connected to a probe pin that carries power supply to the device tested;
a power line coupling the power-carrying electrode and the power being interface electrode together; and
a blowout portion including fuse wiring, the fuse wiring inserted in the power line and having a smaller current capacity than the power line,
wherein the multilayer circuit board includes a ceramic layer and a resin layer on the ceramic layer, the ceramic layer is closer to the mother substrate than the resin layer;
the power line has an exposed portion that is exposed on a surface of the mother substrate or the multilayer circuit board; and
the blowout portion is in the exposed portion of the power line.

2. The probe card according to claim 1, wherein in the blowout portion there is a chip component that comprises the fuse wiring.

3. The probe card according to claim 1, wherein the fuse wiring has a line width smaller than a line width of the power line.

4. The probe card according to claim 1, wherein the fuse wiring comprises conductive paste.

5. The probe card according to claim 1, wherein the blowout portion is on the multilayer circuit board.

6. The probe card according to claim 5, wherein:
the power interface electrode is in the center of the main surface of the multilayer circuit board opposite to the mother substrate in plan view; and
the blowout portion is in a peripheral portion of the main surface opposite to the mother substrate.

7. The probe card according to claim 1, wherein the blowout portion is on the mother substrate.

8. A multilayer circuit board in a probe card used in electrical testing of a device, the multilayer circuit board comprising:
a ceramic layer;
a resin layer on the ceramic layer;
a power interface electrode on a main surface of the resin layer opposite to the ceramic layer, the power interface electrode being connected to a probe pin that carries power supply to the device tested;
a power-carrying outer electrode on a main surface of the ceramic layer opposite to the resin layer;
a power line coupling the power-carrying outer electrode and the power interface electrode together; and
a blowout portion including fuse wiring, the fuse wiring being inserted in the power line and having a smaller current capacity than the power line,
wherein the power line has an exposed portion that is exposed on a surface of the resin layer; and
the blowout portion is in the exposed portion of the power line.

9. A multilayer circuit board in a probe card used in electrical testing of a device, the multilayer circuit board comprising:
a ceramic layer;
a resin layer on the ceramic layer, an area of the resin layer being smaller in area than the ceramic layer in plan view;
a power interface electrode on a main surface of the resin layer opposite to the ceramic layer, the power interface electrode being connected to a probe pin that carries power supply to the device tested;
a power-carrying outer electrode on a main surface of the ceramic layer opposite to the resin layer;
a power line coupling the power-carrying outer electrode and the power interface electrode together; and
a blowout portion including fuse wiring, the fuse wiring being inserted in the power line and having a smaller current capacity than the power line,
wherein the power line has an exposed portion that is exposed on a main surface of the ceramic layer facing the resin layer and in a region not occupied by the resin layer; and
the blowout portion is in the exposed portion of the power line.

10. The probe card according to claim 2, wherein the fuse wiring has a line width smaller than a line width of the power line.

11. The probe card according to claim 2, wherein the fuse wiring comprises conductive paste.

12. The probe card according to claim 3, wherein the fuse wiring comprises conductive paste.

13. The probe card according to claim 2, wherein the blowout portion is on the multilayer circuit board.

14. The probe card according to claim 3, wherein the blowout portion is on the multilayer circuit board.

15. The probe card according to claim 4, wherein the blowout portion is on the multilayer circuit board.

16. The probe card according to claim 2, wherein the blowout portion is on the mother substrate.

17. The probe card according to claim 3, wherein the blowout portion is on the mother substrate.

18. The probe card according to claim 4, wherein the blowout portion is on the mother substrate.
